(19) United States
(12) Patent Application Publication
(10) Pub. No.: US 2022/0102565 A1
(43) Pub. Date: Mar. 31, 2022

(54) PHOTOVOLTAIC CELL, MANUFACTURING METHOD THEREOF, AND PHOTOVOLTAIC BATTERY MODULE

(71) Applicant: National Institute of Advanced Industrial Science and Technology, Tokyo (JP)

(72) Inventors: Sachiko JONAI, Ibaraki (JP); Atsushi MASUDA, Ibaraki (JP); Takashi KOIDA, Ibaraki (JP); Hajime SHIBATA, Ibaraki (JP)

(21) Appl. No.: 17/426,698

(22) PCT Filed: Aug. 26, 2019
(86) PCT No.: PCT/JP2019/033299

§ 371 Date: Jul. 29, 2021

(30) Foreign Application Priority Data
Jan. 30, 2019 (JP) 2019-013756

(51) Int. Cl. H01L 31/049; H01L 31/0216; H01L 31/0224; H01L 31/0236; H01L 31/18

(52) U.S. Cl. CPC H01L 31/049; H01L 31/02168; H01L 31/022458; H01L 31/1884; H01L 31/022483; H01L 31/02363; H01L 31/022475

(57) ABSTRACT

The purpose of the present invention is to improve the reliability of a photovoltaic cell. In the present invention, a photovoltaic cell (CL) comprises a back electrode (BE), a p-type semiconductor layer (semiconductor substrate 1S) disposed on the back electrode (BE), and an n-type semiconductor layer (NL) disposed on the semiconductor substrate (1S). The photovoltaic cell (CL) furthermore comprises: an anti-reflection film (ARF) disposed on the n-type semiconductor layer (NL), the anti-reflection film (ARF) being made of an insulating film; surface electrodes (SE) penetrating the anti-reflection film (ARF) to reach the n-type semiconductor layer (NL); and an electroconductive film (CF) disposed on the anti-reflection film (ARF) so as to cover the surface electrodes (SE), the electroconductive film (CF) being transparent and being electrically connected to the n-type semiconductor layer (NL).

### TECHNICAL FIELD

The present invention relates to a photovoltaic cell, a manufacturing method of the photovoltaic cell, and a photovoltaic module.

### BACKGROUND ART

WO2017/169441 (PTL 1) discloses that an anti-reflection film included in a photovoltaic cell is formed of a silicon rich silicon nitride film.

WO2017/175524 (PTL 2) discloses a technique of adding a capturing additives that captures sodium ions to an encapsulant that encapsulates a photovoltaic cell.

Japanese Unexamined Patent Application Publication (Translation of PCT Application) No. 2008-532311 (PTL 3) discloses a technique of providing a conductive path for extracting charge from the front side of the photovoltaic cell to the bulk.

### CITATION LIST

### Patent Literature

### PTL 1

### WO2017/169441

### PTL 2

### WO2017/175524

### PTL 3

### Japanese Unexamined Patent Application Publication (Translation of PCT Application) No. 2008-532311

### SUMMARY OF INVENTION

### Technical Problem

The development of clean energy sources is desirable from the perspective of global environmental problems such as the depletion of fossil fuels and the increase of carbon dioxide (greenhouse gas) in the atmosphere. As an example, photovoltaic power generation using photovoltaic cells has been commercialized as a new clean energy source.

In particular, in recent years, the use of photovoltaic modules with multiple photovoltaic cells connected to each other has become widespread in households, and large-scale power generation facilities, so-called megawatt-class solar facilities, have been constructed using many photovoltaic modules.

Photovoltaic modules are used outdoors for long periods of time. For this reason, photovoltaic cell modules are required to have long-term reliability in harsh outdoor environments.

In this regard, it has been reported that the power generation efficiency of photovoltaic cells decreases due to potential induced degradation (PID), which is the deterioration of photovoltaic cells. An investigation into the causes of PID and the early establishment of remedial measures are highly desirable.

Other issues and novel features will become apparent from the description herein and the accompanying drawings.

### Solution to Problem

A photovoltaic cell of an embodiment of the present invention includes a back electrode; a first semiconductor layer of a first conductivity type disposed on the back electrode; a second semiconductor layer of a second conductivity type disposed on the first semiconductor layer; an anti-reflection film disposed on the second semiconductor layer, the anti-reflection film being made of an insulating film; a surface electrode extending through the anti-reflection film to reach the second semiconductor layer; and a conductive film disposed on the anti-reflection film so as to cover the surface electrode and electrically connected to the second semiconductor layer, the conductive film being optically transparent.

### Advantageous Effects of Invention

According to the embodiment, the PID can be suppressed, and as a result the reliability of the photovoltaic cell can be improved.

### BRIEF DESCRIPTION OF DRAWINGS

FIG. 1 is a drawing schematically illustrating a configuration of a typical photovoltaic power generation system;

FIG. 2 is a partial sectional view illustrating a part of a photovoltaic module;

FIG. 3 is an enlarged view of a circular region illustrated in FIG. 2;

FIG. 4 is a plan view illustrating a schematic configuration of a photovoltaic cell of the embodiment;

FIG. 5 is a schematic sectional view taken along line A-A of FIG. 4;

FIG. 6 is a flowchart of a manufacturing process of a photovoltaic cell;

FIG. 7 is a sectional view illustrating a configuration of a photovoltaic module of the embodiment;

FIG. 8 is a drawing illustrating a state where a negative potential relative to a frame potential of a module frame is applied to a photovoltaic cell in the photovoltaic module of the embodiment;

FIG. 9 is a drawing illustrating a circular region of FIG. 8 in an enlarged manner;

FIG. 10 is a drawing illustrating a schematic configuration of an acceleration test;

FIG. 11 is a graph illustrating a result of an acceleration test conducted with the configuration illustrated in FIG. 10;

FIG. 12 is a graph illustrating a relationship between the current density and the voltage measured in a light irradiation state using a solar simulator in a photovoltaic module of the related art with no conductive film;

FIG. 13 is a graph illustrating a relationship between the current density and the voltage measured in a light irradiation state using a solar simulator in the photovoltaic module of the present embodiment with a conductive film; and

FIG. 14 is a sectional view illustrating a schematic structure of a photovoltaic cell having a PERC structure.

### DESCRIPTION OF EMBODIMENTS

In all diagrams for describing an embodiment, the same components are basically denoted with the same reference numerals, and reiterated descriptions are omitted. Note that for clarity of the drawing, hatching may be added even in the plan view.

### Generation of High Voltage in Photovoltaic Power Generation System

For example, in a photovoltaic power generation system, a plurality of photovoltaic modules is connected in series to increase the system voltage.

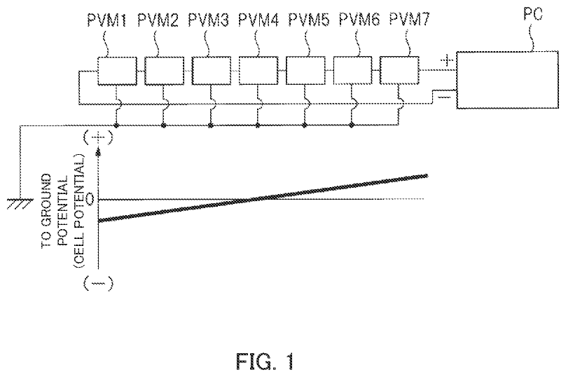

FIG. 1 is a drawing schematically illustrating a configuration of a typical photovoltaic power generation system.

As illustrated in FIG. 1, for example, photovoltaic modules PVM1 to PVM7 are connected in series, and connected to power conditioner PC. Further, the module frame of each of photovoltaic modules PVM1 to PVM7 is electrically connected and set to ground potential (reference potential). That is, the potential (frame potential) of the module frame of each of photovoltaic modules PVM1 to PVM7 is 0 V. On the other hand, since photovoltaic modules PVM1 to PVM7 are connected in series, the output voltages are added together and output to power conditioner PC. Accordingly, as illustrated in FIG. 1, in photovoltaic module PVM7, the potential (cell potential) of the photovoltaic cell is a high and positive potential (several hundred V) relative to the ground potential, which is the potential of the module frame. On the other hand, in photovoltaic module PVM1, the potential of the photovoltaic cell is a low and negative potential (−several hundred V) relative to the ground potential, which is the potential of the module frame. In this manner, the photovoltaic power generation system has a configuration in which a plurality of photovoltaic modules is connected in series, and as a result, in the photovoltaic module (photovoltaic module PVM7 in FIG. 1) close to the output side, the cell potential of the photovoltaic cell is a high and positive potential relative to the frame potential of the module frame. On the other hand, in the photovoltaic module (photovoltaic module PVM1 in FIG. 1) remote from the output side, the cell potential of the photovoltaic cell is a low and negative potential relative to the frame potential of the module frame.

### Room for Improvement

The following describes an actual room for improvement in a photovoltaic module, such as photovoltaic module PVM1 illustrated in FIG. 1, in which the cell potential of the photovoltaic cell is low relative to the frame potential of the module frame (ground potential).

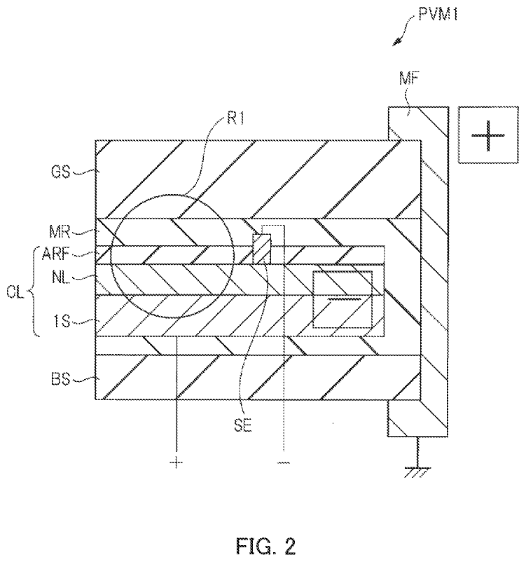

FIG. 2 is a partial sectional view illustrating a part of photovoltaic module PVM1.

In FIG. 2, photovoltaic module PVM1 includes photovoltaic cell CL, and encapsulant MR that encapsulates photovoltaic cell CL. Further, photovoltaic module PVM1 includes back sheet BS disposed at the bottom surface of encapsulant MR, and cover glass GS disposed at the top surface of encapsulant MR. Further, photovoltaic module PVM1 includes module frame MF to which a frame potential (ground potential) is supplied.

As illustrated in FIG. 2, photovoltaic cell CL included in photovoltaic module PVM1 having the above-described configuration includes semiconductor substrate 1S (p-type semiconductor layer) made of a p-type semiconductor material, n-type semiconductor layer NL formed at semiconductor substrate 1S, and anti-reflection film ARF formed at the surface of n-type semiconductor layer NL. Further, photovoltaic cell CL includes surface electrode SE that extends through anti-reflection film ARF to reach n-type semiconductor layer NL. Surface electrode SE is made of silver, for example, and electrically connected to n-type semiconductor layer NL. On the other hand, although not illustrated in FIG. 2, a back electrode made of aluminum, for example, is formed at the back surface of semiconductor substrate 1S. In this manner, photovoltaic cell CL is configured.

Here, it is known that the power generation efficiency decreases when a high voltage is applied between the module frame MF and the photovoltaic cell CL, and this phenomenon is called “PID”. The “PID” is known to occur especially when semiconductor substrate 1S made of p-type semiconductor material is used and the potential of the photovoltaic cell CL becomes negative relative to the frame potential of the module frame ME

In view of this, a focus is directed to a case where a negative potential relative to module frame MF is applied to photovoltaic cell CL in photovoltaic module PVM1 illustrated in FIG. 2.

With reference to the drawings, the following describes a cause of the occurrence of “PID” in a case where a negative potential relative to module frame MF is applied to photovoltaic cell CL.

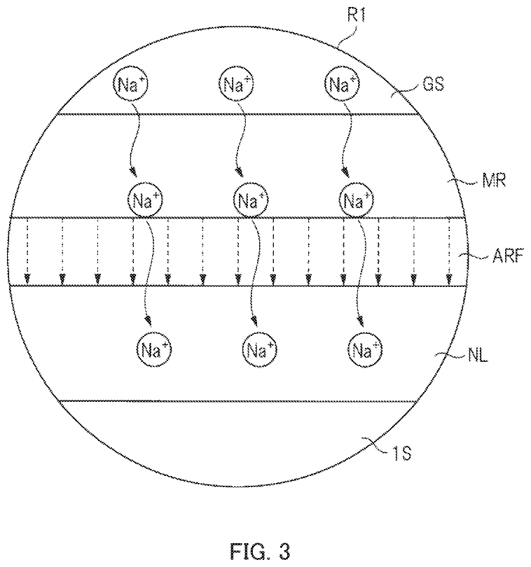

FIG. 3 is an enlarged view of region R1 illustrated in FIG. 2.

In FIG. 3, n-type semiconductor layer NL is formed on semiconductor substrate 1S made of a p-type semiconductor material, and anti-reflection film ARF made of an insulating film such as a silicon nitride film, for example, is formed on n-type semiconductor layer NL. Further, encapsulant MR is disposed in such a manner as to cover anti-reflection film ARF, and cover glass GS is disposed on encapsulant MR.

Here, cover glass GS contains cations such as sodium ions. Further, when a negative potential relative to the module frame is applied to the photovoltaic cell, the cations contained in the glass are accumulated at the surface of anti-reflection film ARF through encapsulant MR. At this time, a high electric field indicated with the broken line arrow(s) in FIG. 3 is generated inside anti-reflection film ARF, which is an insulating film, due to the application of the negative potential relative to the module frame to the photovoltaic cell since anti-reflection film ARF is made of an insulating film such as a silicon nitride film, for example. As a result, with the high electric field generated inside anti-reflection film ARF, the cations accumulated at the surface of anti-reflection film ARF migrate to the inside of the photovoltaic cell through anti-reflection film ARF. Specifically, the cations reach the inside of semiconductor substrate 1S where n-type semiconductor layer NL is formed. Although the mechanism is not clear, it is known that “PID” is caused by cations reaching the inside of semiconductor substrate 1S including n-type semiconductor layer NL. This means that the generation of “PID” is suppressed when the migration of cations such as sodium ions into the photovoltaic cell can be suppressed.

In view of this, in the present embodiment, a configuration for suppressing the migration of cations into the photovoltaic cell is provided based on the knowledge that

“PID” is caused by cations reaching the inside of semiconductor substrate 1S including n-type semiconductor layer NL. The following describes technical ideas of the present embodiment using such a configuration.

### Configuration of Photovoltaic Cell of Embodiment

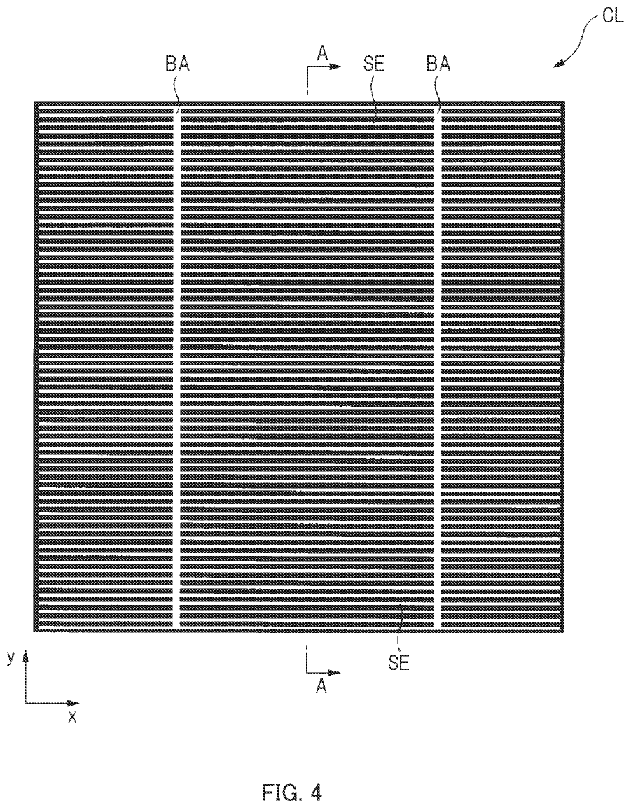

FIG. 4 is a plan view illustrating a schematic configuration of the photovoltaic cell of the present embodiment.

As illustrated in FIG. 4, photovoltaic cell CL of the present embodiment has a rectangular shape, and includes a plurality of surface electrodes SE (so-called finger electrodes). The plurality of surface electrodes SE is disposed side by side in the y direction, for example. Further, each of the plurality of surface electrodes SE extends in the x direction. Further, photovoltaic cell CL of the present embodiment includes bus bar BA (so-called bus bar electrode) electrically connected to the plurality of surface electrodes SE, and bus bar BA extends in the y direction.

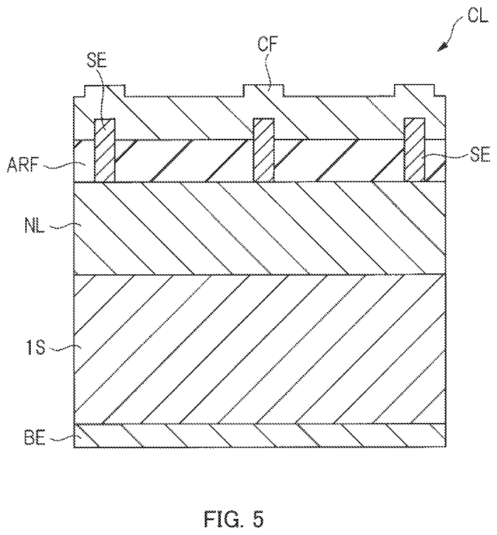

Next, FIG. 5 is a schematic sectional view taken along line A-A of FIG. 4.

Photovoltaic cell CL illustrated in FIG. 5 is typically called, but not limited to, a back surface field (BSF) cell.

In FIG. 5, photovoltaic cell CL of the present embodiment includes semiconductor substrate 1S, which is a p-type semiconductor layer, and n-type semiconductor layer NL is formed at the surface of semiconductor substrate 1S.

Semiconductor substrate 1S is composed of silicon to which a p-type impurity (acceptor) such as boron (B), for example, is introduced, and is a p-type semiconductor layer. Semiconductor substrate 1S, which functions as a p-type semiconductor layer, has a thickness of approximately 200 μm, for example.

In contrast, n-type semiconductor layer NL formed at the surface of semiconductor substrate 1S is a semiconductor layer in which an n-type impurity (donor) such as phosphorus (P), for example, is introduced to silicon, and n-type semiconductor layer NL has a thickness of approximately 0.3 μm, for example. Thus, a pn-junction is formed between semiconductor substrate 1S, which is a p-type semiconductor layer, and n-type semiconductor layer NL.

Note that although not illustrated in the drawings, a random texture structure (irregular structure) of approximately several micrometers is formed at the surface of n-type semiconductor layer NL and the back surface of semiconductor substrate 1S.

Next, as illustrated in FIG. 5, back electrode BE is formed at the back surface of semiconductor substrate 1S. Back electrode BE is formed of an aluminum film, for example. Anti-reflection film ARF is formed on n-type semiconductor layer NL formed at the surface of semiconductor substrate 1S. Anti-reflection film ARF is formed of a silicon nitride film and/or a silicon oxide film, for example. Note that although not illustrated in the drawings, an irregular structure called texture structure is formed in an interface region between n-type semiconductor layer NL and anti-reflection film ARF. In other words, it can be said that an irregular structure is formed at the surface of n-type semiconductor layer NL. The irregular structure is provided to prevent reflection of incident sunlight. That is, with a synergistic effect of anti-reflection film ARF and the irregular structure, photovoltaic cell CL of the present embodiment can effectively suppress reflection of sunlight incident on photovoltaic cell CL. As a result, photovoltaic cell CL of the present embodiment can improve the use efficiency of sunlight.

Next, photovoltaic cell CL of the present embodiment includes the plurality of surface electrodes SE that extends through anti-reflection film ARF to reach n-type semiconductor layer NL. That is, each of the plurality of surface electrodes SE and n-type semiconductor layer NL are electrically connected to each other.

Note that while FIG. 5 simply illustrates only three surface electrodes SE, more surface electrodes SE are formed at photovoltaic cell CL in practice.

Surface electrode SE is composed of silver, for example.

Next, as illustrated in FIG. 5, photovoltaic cell CL of the present embodiment includes conductive film CF formed on anti-reflection film ARF so as to cover surface electrode SE. Here, “conductive film” refers to any film that is conductive in a broad sense, including so-called conductor films and semiconductor films.

Conductive film CF is in contact with surface electrode SE, and thus conductive film CF and surface electrode SE are electrically connected to each other. Further, as illustrated in FIG. 5, surface electrode SE is in contact with n-type semiconductor layer NL, and thus conductive film CF is electrically connected to n-type semiconductor layer NL through surface electrode SE.

Further, conductive film CF is optically transparent. Specifically, desirably, conductive film CF is composed of a material that is optically transparent at least to visible light and infrared light, which are main components of sunlight, more desirably a material with high transmittance, for example.

Specifically, conductive film CF may be composed of a film including indium and oxygen, or a film including zinc and oxygen. For example, conductive film CF may be composed of a film containing indium oxide doped with tin. It should be noted that conductive film CF is not limited to this, and may be composed of an indium oxide film doped with tungsten, an indium oxide film doped with cerium, an indium oxide film doped with hydrogen, a zinc oxide film doped with aluminum, a zinc oxide film doped with gallium, a tin oxide film doped with fluorine or the like. Conductive film CF having the above-described configuration has a conductivity of 10 siemens/cm or greater, for example. In addition, conductive film CF has a film thickness greater than 0 nm and smaller than or equal to 100 nm, for example. More preferably, conductive film CF has a film thickness of 20 nm to 80 nm.

Photovoltaic cell CL of the present embodiment has the above-described configuration, and an overview of the configuration of photovoltaic cell CL is as follows. Photovoltaic cell CL of the present embodiment includes back electrode BE, semiconductor substrate 1S, which is a p-type semiconductor layer, disposed on back electrode BE, and n-type semiconductor layer NL formed on p-type semiconductor layer. Further, photovoltaic cell CL of the present embodiment includes anti-reflection film ARF formed on n-type semiconductor layer NL and made of an insulating film, surface electrode

SE that extends through anti-reflection film ARF to reach n-type semiconductor layer NL, and optically transparent conductive film CF formed on anti-reflection film ARF so as to cover surface electrode SE and electrically connected to the n-type semiconductor layer NL.

### Operation of Photovoltaic Cell of Embodiment

Photovoltaic cell CL of the present embodiment is configured as described above, and its operation is described below with reference to FIG. 5.

First, in FIG. 5, when sunlight containing visible light and infrared light is applied from the upper side of photovoltaic cell CL, the sunlight is applied to conductive film CF, which is a component of photovoltaic cell CL. At this time, conductive film CF transmits the sunlight since conductive film CF is composed of a material that is optically transparent at least to visible light and infrared light as main components of sunlight. Here, when conductive film CF has an excessively large film thickness, the loss of sunlight that is transmitted through conductive film CF increases, and therefore the film thickness of conductive film CF is desirably 100 nm or smaller.

Next, the sunlight transmitted through conductive film CF impinges on anti-reflection film ARF. Since anti-reflection film ARF is composed of a silicon oxide film and/or a silicon nitride film that is transparent to visible light and infrared light as main components of sunlight, the sunlight transmitted through conductive film CF so as to impinge on anti-reflection film ARF is also transmitted through anti-reflection film ARF. Here, the film thickness of anti-reflection film ARF is adjusted in such a manner as to reduce the reflection of the sunlight, and thus the reflection of the sunlight at anti-reflection film ARF is suppressed. As a result, the loss of the sunlight transmitted through anti-reflection film ARF can be reduced.

Subsequently, the sunlight transmitted through anti-reflection film ARF enters the inside of photovoltaic cell CL located below anti-reflection film ARF. More specifically, the sunlight enters n-type semiconductor layer NL, the pn-junction part formed in the interface region between n-type semiconductor layer NL and semiconductor substrate 1S (p-type semiconductor layer), and semiconductor substrate 1S.

At this time, for example, the light energy of visible light and infrared light as main components of the sunlight is greater than the band gap of silicon, and therefore electrons in the valence band of silicon are excited into the conduction band by receiving light energy supplied by the sunlight (visible light and infrared light). This results in accumulation of electrons in the conduction band and generation of holes in the valence band. In this manner, irradiation of photovoltaic cell CL with sunlight results in excitation of electrons in the conduction band and generation of holes in the valence band. Further, the conduction band of the n-type semiconductor layer constituting one of the pn-junctions is at a lower electronic energy level than the conduction band of semiconductor substrate 1S, which is the p-type semiconductor layer constituting the other part of the pn-j unction. As a result, electrons excited in the conduction band are moved to n-type semiconductor layer NL, and thus electrons are accumulated in the n-type semiconductor layer NL. On the other hand, holes in the valence band are moved to semiconductor substrate 1S (p-type semiconductor layer) and thus holes are accumulated in semiconductor substrate 1S (p-type semiconductor layer). As a result, an electromotive force is generated between semiconductor substrate 1S, which is a p-type semiconductor layer, and n-type semiconductor layer NL. Further, for example, when a load is connected between surface electrode SE electrically connected to n-type semiconductor layer NL, and back electrode BE electrically connected to semiconductor substrate 1S, electrons flow from surface electrode SE through the load to back electrode BE. In other words, current flows from back electrode BE through the load to the surface electrode SE. In this manner, the load can be driven by operating photovoltaic cell CL.

### Manufacturing Method of Photovoltaic Cell of Embodiment

Next, a manufacturing method of the photovoltaic cell of the present embodiment is described.

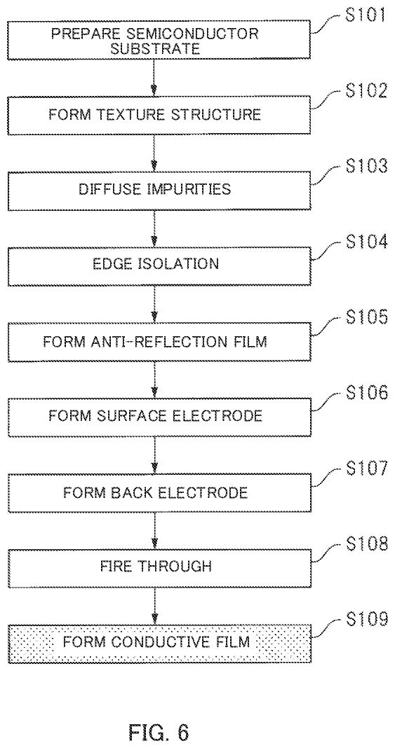

FIG. 6 is a flowchart of a manufacturing process of a photovoltaic cell.

First, for example, a semiconductor substrate made of single crystal silicon or polycrystalline silicon with p-type impurities (acceptor) added is prepared. This semiconductor substrate has a flat planar shape (S101).

Next, a texture structure as an anti-reflection structure is formed at the surface (light reception surface) of the semiconductor substrate using a wet etching technique, for example. The texture structure is composed of an irregular structure, and formed to achieve a reflection reduction effect and an incident light confinement effect (S102).

Subsequently, an n-type semiconductor layer is formed on the surface side of the semiconductor substrate by diffusing n-type impurities at the surface of the semiconductor substrate (S103). For example, phosphorus (P) may be used as n-type impurities. As a result, an n-type semiconductor layer is formed in a part of the semiconductor substrate that functions as a p-type semiconductor layer, and the pn-junction part is formed in the interface region between the p-type semiconductor layer and the n-type semiconductor layer.

Thereafter, edge isolation is performed on the semiconductor substrate where the n-type semiconductor layer is formed (S104). Specifically, since n-type semiconductor regions are also formed on the sides of the semiconductor substrate due to the diffusion of phosphorus during the formation of the n-type semiconductor layer on the substrate, edge isolation is performed to remove the n-type semiconductor regions formed on the sides of the semiconductor substrate.

Next, an anti-reflection film is formed on the n-type semiconductor layer formed at the surface of the semiconductor substrate (S105). This anti-reflection film is composed of, for example, a silicon oxide film or a silicon nitride film, and is formed by, for example, a chemical vapor deposition (CVD) method.

Subsequently, a surface electrode is formed at the surface of the anti-reflection film (S106). This surface electrode is made of, for example, silver, and is formed by a printing method using silver paste. Thereafter, a back electrode is formed at the back surface of semiconductor substrate (S107). This back electrode is composed of, for example, aluminum, and is formed by a printing method.

Thereafter, a fire-through process is performed on the semiconductor substrate (S108). The fire-through process is a process in which through an application of a heat treatment of 800° C. or higher to the semiconductor substrate, the surface electrode formed on the anti-reflection film extends through the anti-reflection film and connects to the n-type semiconductor layer formed below the anti-reflection film. Through such a fire-through process, the surface electrode composed of a silver electrode is electrically connected to the n-type semiconductor layer.

Next, a conductive film that covers the surface electrode and is transparent to at least visible light and infrared light as main components of the sunlight is formed on the anti-reflection film (S109). This conductive film is composed of, for example, a film including indium and oxygen and/or a film including zinc and oxygen, and can be formed by using a solution coating method in air or a sputtering or evaporation method in a vacuum, for example.

In the above-described manner, the photovoltaic cell of the present embodiment can be manufactured.

### Configuration of Photovoltaic Module of Embodiment

Next, a schematic configuration of photovoltaic module PVM using photovoltaic cell CL of the present embodiment is described with reference to the drawings.

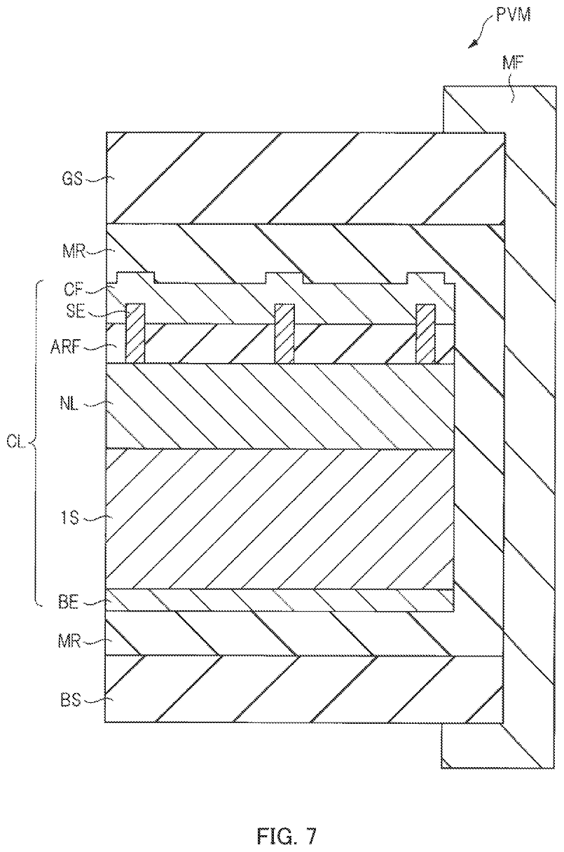

FIG. 7 is a sectional view illustrating a configuration of the photovoltaic module of the present embodiment.

In FIG. 7, photovoltaic module PVM of the present embodiment includes photovoltaic cell CL having the structure illustrated in FIG. 5, encapsulant MR that encapsulates photovoltaic cell CL, back sheet BS disposed at the bottom surface of encapsulant MR, cover glass GS disposed on the top surface of encapsulant MR, and module frame MF to which a ground potential is supplied. Desirably, cover glass GS is composed of a material that is optically transparent at least to visible light and infrared light, which are main components of sunlight, more desirably a material with high transmittance, for example. A reason for this is that with cover glass GS having a high transmittance, the reflection and absorption of sunlight are suppressed and the amount of sunlight that enters the inside of photovoltaic module PVM through cover glass GS is increased, thus making it possible to improve the power generation efficiency.

### Features of Embodiment

Next, features of the present embodiment are described.

A feature of the present embodiment is that conductive film CF that covers surface electrode SE is formed on anti-reflection film ARF as illustrated in FIG. 5, for example. Thus, conductive film CF is electrically connected to n-type semiconductor layer NL located below anti-reflection film ARF. A reason for this is that since n-type semiconductor layer NL is in contact with surface electrode SE and conductive film CF is also in contact with surface electrode SE as illustrated in FIG. 5, conductive film CF is thus electrically connected to n-type semiconductor layer NL through surface electrode SE.

As a result, conductive film CF and n-type semiconductor layer NL have the same potential. This means that no electric field is generated inside anti-reflection film ARF, which is an insulating film sandwiched by conductive film CF and n-type semiconductor layer NL. That is, with a feature of the present embodiment in which conductive film CF that covers surface electrode SE is formed on anti-reflection film ARF, conductive film CF and n-type semiconductor layer NL that sandwich anti-reflection film ARF have the same potential, and as a result the electric field generated inside anti-reflection film ARF can be set to substantially zero.

Further, when the electric field generated inside anti-reflection film ARF can be set to substantially zero, it is possible to prevent cations such as sodium ions from reaching the inside of semiconductor substrate 1S including n-type semiconductor layer NL. Accordingly, in light of the knowledge that “PID” is caused by cations reaching the inside of semiconductor substrate 1S including n-type semiconductor layer NL, when a feature of the present embodiment in which conductive film CF that covers surface electrode SE is formed on anti-reflection film ARF is employed, “PID” can be effectively suppressed and as a result the reliability of the photovoltaic cell can be improved.

The following specifically describes that the above-described feature point can suppress “PID”.

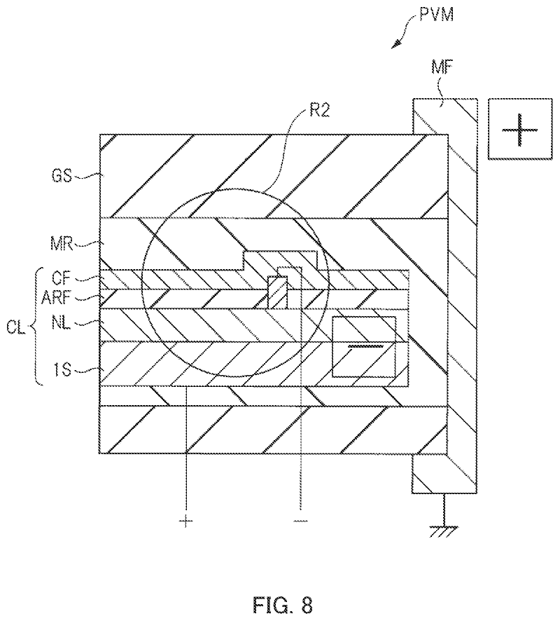

FIG. 8 is a drawing illustrating a state where a negative potential relative to the frame potential of the module frame is applied to a photovoltaic cell in the photovoltaic module of the present embodiment.

In FIG. 8, the frame potential of module frame MF is the ground potential, whereas a negative potential relative to module frame MF is applied to photovoltaic cell CL. As a result, a high potential difference is generated between module frame MF and photovoltaic cell CL. This means that in photovoltaic module PVM, a high electric field is generated between module frame MF and photovoltaic cell CL. However, in the present embodiment, even when a negative potential relative to module frame MF is applied to photovoltaic cell CL, “PID” due to this can be suppressed. This mechanism is specifically described below.

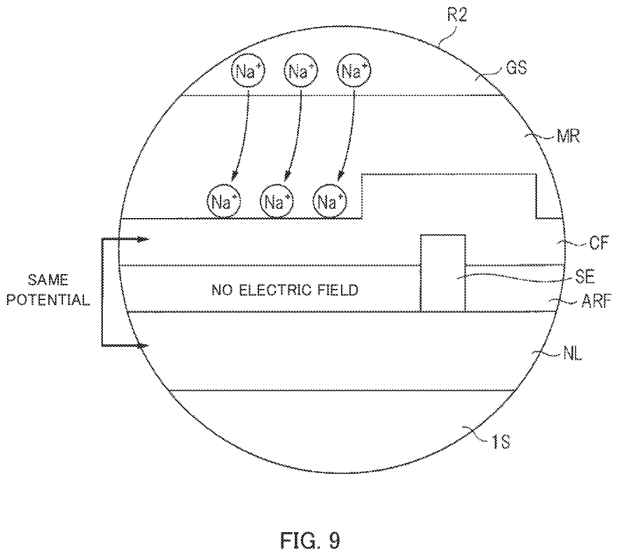

FIG. 9 is a drawing illustrating region R2 of FIG. 8 in an enlarged manner.

In FIG. 9, n-type semiconductor layer NL is formed on semiconductor substrate 1S composed of a p-type semiconductor material, and anti-reflection film ARF is formed on n-type semiconductor layer NL. Further, surface electrode SE is formed so as extend through anti-reflection film ARF to reach n-type semiconductor layer NL, and conductive film CF is formed on anti-reflection film ARF so as to cover surface electrode SE. Further, encapsulant MR is disposed on conductive film CF and cover glass GS is disposed on encapsulant MR.

Here, as illustrated in FIG. 9, conductive film CF is in contact with surface electrode SE and n-type semiconductor layer NL is also in contact with surface electrode SE, and thus, conductive film CF and n-type semiconductor layer NL are electrically connected through surface electrode SE. That is, conductive film CF and n-type semiconductor layer NL have the same potential, and anti-reflection film ARF, which is an insulator, is thus sandwiched between conductive film CF and n-type semiconductor layer NL having the same potential.

As a result, for example, as illustrated in FIG. 8, even when a negative potential relative to module frame MF is applied to photovoltaic cell CL, no high electric field is generated inside anti-reflection film ARF composed of an insulator. A reason for this is that since conductive film CF is formed on anti-reflection film ARF, the electric field generated by the potential difference between module frame MF and photovoltaic cell CL is blocked by conductive film CF. Further, conductive film CF is electrically connected to n-type semiconductor layer NL by surface electrode SE, and conductive film CF and n-type semiconductor layer NL have the same potential. As a result, since anti-reflection film ARF is sandwiched between conductive film CF and n-type semiconductor layer NL having the same potential, the potential difference between the bottom surface and top surface of anti-reflection film ARF is substantially zero. This means that the electric field applied to the inside of anti-reflection film ARF, which is an insulator, is substantially zero. At this time, as illustrated in FIG. 9, with an electric field generated by a negative potential relative to module frame MF applied to photovoltaic cell CL, the cations such as sodium ions included in cover glass GS move to the interface region between encapsulant MR and conductive film CF. However, since conductive film CF and n-type semiconductor layer NL are electrically connected by surface electrode SE so as to have the same potential, the electric field inside anti-reflection film ARF sandwiched between conductive film CF and n-type semiconductor layer NL is substantially zero. As a result, the cations accumulated in the interface region between encapsulant MR and conductive film CF are less likely to migrate to the inside of anti-reflection film ARF. That is, in the present embodiment, no electric field is generated inside anti-reflection film ARF, and thus migration of cations into photovoltaic cell CL through anti-reflection film ARF can be effectively suppressed.

In this manner, photovoltaic module PVM of the present embodiment can suppress “PID” due to migration of cations such as sodium ions into photovoltaic cell CL. Thus, the present embodiment can improve the reliability of photovoltaic module PVM.

From the viewpoint of suppressing “PID”, it is important to set the electric field generated inside anti-reflection film ARF to substantially zero, and this means that it is important to set conductive film CF and n-type semiconductor layer NL that sandwich anti-reflection film ARF to the same potential. Further, in order to set conductive film CF and n-type semiconductor layer NL that sandwich anti-reflection film ARF to the same potential, it is desirable that the conductivity of conductive film CF be high. A reason for this is that a low conductivity of conductive film CF means a high parasitic resistance of conductive film CF, and then the potential of conductive film CF easily floats from the potential of n-type semiconductor layer NL. In this case, a potential difference is generated between conductive film CF and n-type semiconductor layer NL that sandwich anti-reflection film ARF, and the electric field generated inside anti-reflection film ARF cannot be set to substantially zero. On the other hand, when the conductivity of conductive film CF is high, the parasitic resistance of conductive film CF is low, and the generation of a potential difference between conductive film CF and n-type semiconductor layer NL due to the parasitic resistance can be suppressed.

For example, desirably, the conductivity of conductive film CF is 10 siemens/cm or greater, as an exemplary specific numerical value. In this case, conductive film CF and n-type semiconductor layer NL that sandwich anti-reflection film ARF can be set to substantially the same potential, and it is confirmed that the generation of “PID” can be thus suppressed.

It should be noted that it is not enough to simply increase the conductivity of the conductive film CF. A reason for this is that when the conductivity is increased, the absorption of infrared rays by free electrons in conductive film CF is increased, which results in a decrease in the photoelectric conversion efficiency (decrease in photoelectric current) of the photovoltaic cell, making it difficult to improve the performance of the photovoltaic cell. It should be noted that since the conductivity is expressed as the product of the carrier mobility and the carrier concentration of conductive film CF, the generation of “PID” can be effectively suppressed while suppressing the reduction of the photoelectric current by increasing the conductivity by increasing the carrier mobility while suppressing the increase of the carrier concentration.

### Verification of Effect of Embodiment

Next, measurement results that support the effectiveness of photovoltaic module PVM of the present embodiment in suppressing “PID” are described.

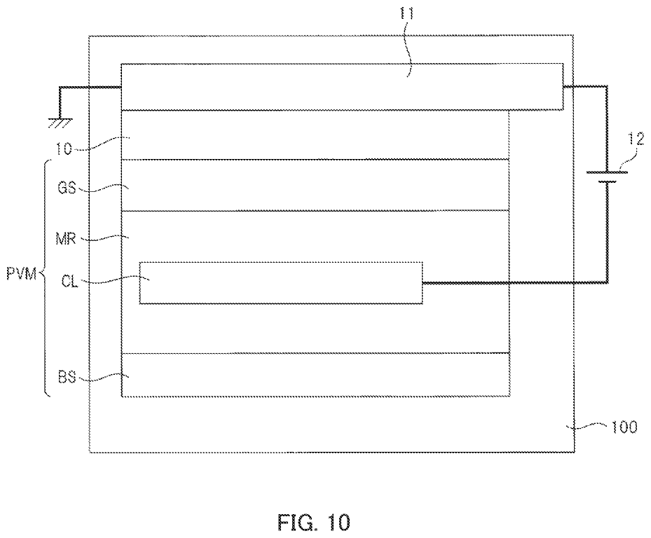

FIG. 10 is a drawing illustrating a schematic configuration of an acceleration test.

In FIG. 10, photovoltaic module PVM includes photovoltaic cell CL, encapsulant MR that encapsulates photovoltaic cell CL, back sheet BS disposed at the bottom surface of encapsulant MR, and cover glass GS disposed at the top surface of encapsulant MR. An acceleration test is conducted using photovoltaic module PVM having the above-described configuration.

More specifically, as illustrated in FIG. 10, the surface electrode (n-type electrode) and the back electrode (p-type electrode) of the photovoltaic cell are short-circuited, and aluminum plate 11 is disposed on photovoltaic module PVM with conductive rubber sheet 10 therebetween. At this time, a ground potential is supplied to aluminum plate 11. Then, as illustrated in FIG. 10, the test piece including photovoltaic module PVM, conductive rubber sheet 10 and aluminum plate 11 is kept in thermostatic oven 100 at a temperature of 85° C. and relative humidity of 2% or less, for example. In this state, the test is conducted by applying a voltage of −2000 V between aluminum plate 11, to which a ground potential is supplied, and photovoltaic cell CL (short-circuit electrode) by DC high-voltage power supply 12 located outside thermostatic oven 100.

As a supplement, after the completion of the predetermined test time, photovoltaic cell module PVM is removed from thermostatic oven 100 and the maximum output retention is measured by using a solar simulator under standard test conditions. After completing the measurement, photovoltaic cell module PVM is introduced into thermostatic oven 100 again to resume the acceleration test.

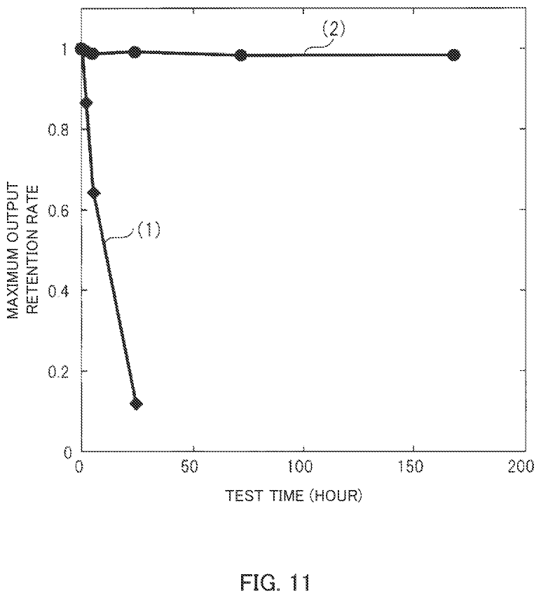

FIG. 11 is a graph illustrating a result of an acceleration test conducted with the configuration illustrated in FIG. 10.

In FIG. 11, the vertical axis indicates the maximum output retention rate, and the horizontal axis indicates the test time.

FIG. 11 illustrates graph (1) corresponding to a photovoltaic module of the related art with no conductive film, and graph (2) corresponding to the photovoltaic module of the present embodiment with a conductive film.

Graph (1) of FIG. 11 shows that in the photovoltaic module of the related art, the maximum output retention rate becomes smaller than 70% of the initial value after two hours from the start of the test, and the maximum output retention rate is reduced to 10% of the initial value after one day (24 hours) from the start of the test. That is, it can be seen that “PID” is generated in the photovoltaic module of the related art.

In contrast, it can be seen that in the photovoltaic module of the present embodiment illustrated in graph (2) of FIG. 11, there is almost no decrease in the maximum output retention rate even after seven days from the start of the test. That is, in the photovoltaic module of the present embodiment, “PID” is suppressed and the reliability of the photovoltaic cell can be improved.

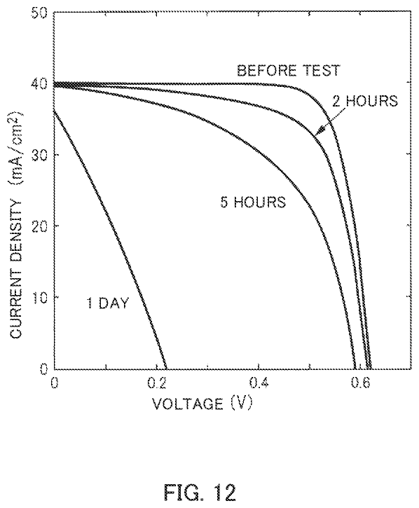

FIG. 12 is a graph illustrating a relationship between the current density and the voltage (current density-voltage property) measured in a light irradiation state using a solar simulator in a photovoltaic module of the related art with no conductive film. As illustrated in FIG. 12, it can be seen that in the photovoltaic module of the related art with no conductive film, the relationship between current density and voltage degrades as time passes from the acceleration test. Here, the intercept between the characteristic curve and the vertical axis represents the short circuit current density, and the intercept between the characteristic curve and the horizontal axis represents the open circuit voltage. In particular, the product of the short circuit current density, the open circuit voltage, the fill factor, and the element area represents the maximum output. Therefore, from the results shown in FIG. 12, it can be seen that the maximum power output of the photovoltaic cell module in the related technology without the conductive film decreases as the time from the acceleration test passes. This means that the “PID” in which the power generation efficiency decreases with time occurs in the photovoltaic module in the related art.

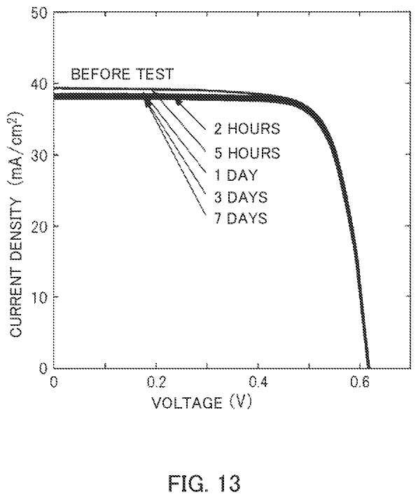

In contrast, FIG. 13 is a graph illustrating a relationship between the current density and the voltage (current density-voltage property) measured in a light irradiation state using the photovoltaic module of the present embodiment with a conductive film. As illustrated in FIG. 13, it can be seen that in the photovoltaic module of the present embodiment, the relationship between the current density and the voltage is substantially constant without change even as time passes from the acceleration test. Accordingly, it can be seen from the results illustrated in FIG. 13 that in the photovoltaic module of the present embodiment with a conductive film, the maximum output does not substantially change even as time passes from the acceleration test. This means that the photovoltaic module of the present embodiment suppresses the “PID” in which the power generation efficiency decreases with time.

In the above-mentioned manner, it can be seen from the results of the acceleration test that the photovoltaic module of the present embodiment suppresses “PID” and can improve the reliability of the photovoltaic cell.

### MODIFICATIONS

The technical ideas of the present embodiment may be applied to a photovoltaic cell having a passivated emitter rear cell (PERC) structure as well as to photovoltaic cell CL illustrated in FIG. 5.

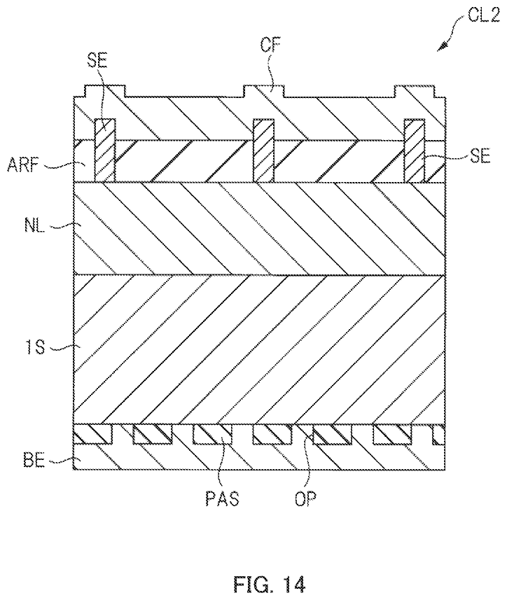

FIG. 14 is a sectional view illustrating a schematic structure of photovoltaic cell CL2 having a PERC structure.

As can be seen from comparison between FIG. 5 and FIG. 14, the back electrode structure of photovoltaic cell CL2 illustrated in FIG. 14 differs from the back electrode structure of photovoltaic cell CL illustrated in FIG. 5. Specifically, in photovoltaic cell CL2 illustrated in FIG. 14, insulating film PAS composed of, for example, a silicon nitride film is formed at the back surface of semiconductor substrate 1S, and opening OP is formed in insulating film PAS through the use of a laser. Further, back electrode BE is formed in such a manner as to embed opening OP provided in insulating film PAS. In photovoltaic cell CL2 having a PERC structure with the above-described configuration, the contact area between semiconductor substrate 1S and back electrode BE is small, and the recombination of electrons and holes caused by defect levels formed on the backside of semiconductor substrate 1S can be suppressed. Thus, with photovoltaic cell CL2 having the PERC structure, the efficiency of the power generation of the photovoltaic cell can be improved, and as a result, the performance of the photovoltaic cell can be advantageously improved.

### Usefulness of Technical Ideas of Embodiment

Finally, the usefulness of the technical ideas of the present embodiment is described.

A knowledge as a basis of the technical ideas of the present embodiment is that one of the possible causes of PID is the migration of cations such as sodium ions into the photovoltaic cell, which is caused by the electric field applied to the inside the anti-reflection film. Further, on the basis of this knowledge, the present embodiment includes a configuration of suppressing the electric field that is applied to the inside of the anti-reflection film. Specifically, the technical idea of the present embodiment is an idea of setting the electric field generated inside the anti-reflection film to substantially zero by forming the conductive film on the anti-reflection film in a sandwiched manner between the conductive film and the n-type semiconductor layer having the same potential, and the capability of this technical idea for suppressing “PID” is supported as illustrated in FIG. 11 to FIG. 13, for example. Accordingly, it can be said that the inventor's novel knowledge that a cause of PID is the migration of cations such as sodium ions into the photovoltaic cell, which is caused by the electric field applied to the inside the anti-reflection film, is valid.

In this regard, for example, PTL 1, which is described in the “Background Art” section, describes the suppression of “PID” by forming the anti-reflection film in the photovoltaic cell from a silicon rich silicon nitride film. However, simply changing the composition of the anti-reflection film is not expected to significantly suppress “PID” because the electric field inside the anti-reflection film cannot be reduced to substantially zero. In other words, in order to effectively suppress “PID,” it is necessary to reduce the electric field generated inside the anti-reflection film to substantially zero, but in the above-mentioned PTL 1, there is no knowledge of reducing the electric field generated inside the anti-reflection film to substantially zero. In other words, while the technology described in PTL 1 focuses on the composition of the anti-reflection film to suppress “PID,” the important knowledge that the electric field applied inside the anti-reflection film is effective against “PID” is neither described nor suggested. That is, the novel knowledge discovered by the inventor captures the essence of suppressing “PID”, and the technical idea in the present embodiment embodied based on this knowledge is superior in that it can significantly suppress “PID”.

Furthermore, PTL 2, which is described in the “Background Art” section, describes a technology for adding a capturing additive that captures sodium ions to the encapsulant that encapsulates the photovoltaic cell. Specifically, although PTL 2 focuses on the fact that sodium ions are the main cause of “PID,” it does not pursue the issue in detail to the point where the problem is that cations represented by sodium ions migrate to the inside of the photovoltaic cell. In the measures described in PTL 2, for example, once the capturing material is saturated, the effect of capturing sodium ions is lost, and the suppression effect on “PID” is limited in that it does not focus on cations other than sodium ions. In contrast, the novel knowledge discovered by the inventor captures the essence for suppressing “PID,” and the technical idea embodied in the present embodiment based on this knowledge is superior in that it can significantly suppress “PID.

FIG. 5C of PTL 3, which is described in the “Background Art” section, describes a technology for forming a conductive layer on an anti-reflection coating. However, PTL 3 neither describes nor suggests the technical idea of the present embodiment of setting the conductive film and the n-type semiconductor layer to the same potential by electrically connecting the conductive film and the n-type semiconductor layer through the surface electrode. Further, PTL 3 does not describe or suggest even the knowledge of reducing the electric field generated inside the anti-reflection film to substantially zero, which is a motivation for achieving the technical idea of the present embodiment. In the first place, the photovoltaic cell in the present embodiment uses a p-type semiconductor substrate, which is inexpensive to manufacture, and the use of the p-type semiconductor substrate raises the problem of the “PID” that occurs when the photovoltaic cell has a negative potential relative to the frame potential. Specifically, PTL 3 uses an n-type silicon wafer as illustrated in FIG. 2 of PTL 3, and the basic configuration differs from that of the present embodiment. The “PID” that is focused on in PTL 3 is the so-called “Surface Polarization Effect,” which is a type of “PID” that occurs when the photovoltaic cell has a positive potential relative to the frame potential, assuming the use of n-type silicon wafers. In contrast, the “PID” focused on in the present embodiment is “PID” that occurs due to the p-type semiconductor substrate, which differs from the “PID” focused on in PTL 3. In other words, the “PID” that is focused on in the present embodiment is the “PID” that occurs when the photovoltaic cell has a negative potential relative to the frame potential. Therefore, it should be additionally noted that the technical idea of the present embodiment is completely different from the technology described in PTL 3.

The inventions made by the inventor are described above in detail based on the embodiments of the inventions, and it goes without saying that the present invention is not limited to the aforementioned embodiments and can be modified in various ways without departing from the gist thereof.

### REFERENCE SIGNS LIST

1S Semiconductor substrate
ARF Anti-reflection film
BE Back electrode
BS Back sheet
CF Conductive film
GS Cover glass
MF Module frame

### MR Encapsulant

NL N-type semiconductor layer
SE Surface electrode

1. A photovoltaic cell comprising:
a back electrode;
a first semiconductor layer of a first conductivity type disposed on the back electrode;
a second semiconductor layer of a second conductivity type disposed on the first semiconductor layer;
an anti-reflection film disposed on the second semiconductor layer, the anti-reflection film being made of an insulating film;
a surface electrode extending through the anti-reflection film to reach the second semiconductor layer; and
a conductive film disposed on the anti-reflection film so as to cover the surface electrode and electrically connected to the second semiconductor layer, the conductive film being optically transparent.

2. The photovoltaic cell according to claim 1, wherein the conductive film has a conductivity of 10 siemens/cm or greater.

3. The photovoltaic cell according to claim 1, wherein the conductive film has a film thickness greater than 0 nm and smaller than or equal to 100 nm.

4. The photovoltaic cell according to claim 1, wherein the conductive film includes a film including indium and oxygen.

5. The photovoltaic cell according to claim 1, wherein the conductive film includes a film including zinc and oxygen.

6. The photovoltaic cell according to claim 1, wherein an irregular structure is formed at a surface of the second semiconductor layer.

7. The photovoltaic cell according to claim 1, wherein the anti-reflection film includes a silicon nitride film.

8. The photovoltaic cell according to claim 1,
wherein the first semiconductor layer is a p-type semiconductor layer; and
wherein the second semiconductor layer is an n-type semiconductor layer.

9. A photovoltaic module comprising:
the photovoltaic cell according to claim 1;
an encapsulant configured to encapsulate the photovoltaic cell;
a back sheet disposed at a bottom surface of the encapsulant;
an optically transparent material disposed at a top surface of the encapsulant; and
a module frame to which a ground potential is supplied.

10. A method of manufacturing a photovoltaic cell, the method comprising:
(a) preparing a semiconductor substrate of a first conductivity type;
(b) forming a semiconductor layer of a second conductivity type at the semiconductor substrate;
(c) forming an anti-reflection film on the semiconductor layer;
(d) forming a back electrode in contact with the semiconductor substrate;
(e) forming a surface electrode on the anti-reflection film;
(f) providing a heat treatment on the semiconductor substrate after the (e); and
(g) forming a conductive film on the anti-reflection film after the (f), the conductive film being configured to cover the surface electrode and configured to be optically transparent,
wherein in the (f), the surface electrode extends through the anti-reflection film to reach the semiconductor layer, and
wherein the conductive film is electrically connected to the semiconductor layer.

11. The method according to claim 10, wherein the forming the conductive film in the (g) is performed using a solution coating method.

12. The method according to claim 10, wherein the forming the conductive film in the (g) is performed using a sputtering method or an evaporation method.
